(19) United States
(12) Patent Application Publication
(10) Pub. No.: US 2026/0147048 A1
(43) Pub. Date: May 28, 2026

(54) METHOD AND APPARATUS FOR GENERATING DIGITAL TWIN OF BATTERY PACKAGE

(71) Applicant: SAMSUNG SDI CO., LTD., Yongin-si (KR)

(72) Inventors: YONGRACK KOO, Yongin-si (KR); MINJEONG KANG, Yongin-si (KR); GIHEON KIM, Yongin-si (KR); JEONGMO KANG, Yongin-si (KR)

(73) Assignee: SAMSUNG SDI CO., LTD., Yongin-si (KR)

(21) Appl. No.: 19/203,056

(22) Filed: May 8, 2025

(30) Foreign Application Priority Data
Nov. 8, 2024 (KR) 10-2024-0158167

(51) Int. Cl. G01R 31/367; G01R 31/374; G01R 31/3842; G01R 31/389; G01R 31/392

(52) U.S. Cl. CPC G01R 31/367; G01R 31/374; G01R 31/3842; G01R 31/389; G01R 31/392

(57) ABSTRACT

A method of generating a digital twin of a battery package includes measuring a battery package to obtain measurement data and pre-processing the obtained measurement data to generate first data, receiving initial data for a battery cell included in the battery package and pre-processing the received initial data to generate second data, generating integrated data based on the first data and the second data, and generating a digital twin corresponding to the battery package based on the generated integrated data.

### CROSS-REFERENCE TO RELATED APPLICATIONS

This present application claims priority to and the benefit under 35 U.S.C. § 119(a)-(d) of Korean Patent Application No. 10-2024-0158167, filed on Nov. 8, 2024, in the Korean Intellectual Property Office, the entire disclosure of which is incorporated herein by reference.

### FIELD

The present disclosure relates to a method for establishing a digital twin of a specific equipment, and more particularly, to a method of establishing a digital twin of a battery package used in a large-capacity battery system such as an electric vehicle or an energy storage system (ESS), and an apparatus for implementing the method.

### BACKGROUND

There has been a method of establishing a digital twin model based on data collected from a battery management system (BMS) of a battery package and predicting the performance and lifespan of a battery in real time through the digital twin model. However, charging/discharging conditions set in the BMS are fixed rather than changing depending on a state of the battery, such that when some of battery cells included in the battery package deteriorate beyond a certain level, the prediction performance of the digital twin model is significantly reduced.

### SUMMARY

The present disclosure provides a method of generating a digital twin of a battery package and an apparatus for implementing the method.

According to aspects of the present disclosure, a method of generating a digital twin of a battery package includes measuring a battery package to obtain measurement data and pre-processing the obtained measurement data to generate first data, receiving initial data for a battery cell included in the battery package and pre-processing the received initial data to generate second data, generating integrated data based on the first data and the second data, and generating a digital twin corresponding to the battery package based on the generated integrated data.

In the method, the measurement data may include data about at least one of current, voltage, and temperature received from a battery management system (BMS) of the battery package.

In the method, the initial data may include a pressure for at least one of battery cells included in the battery package.

In the method, the initial data may include an impedance for at least one of battery cells included in the battery package.

In the method, the initial data may include a temperature change curve for at least one of battery cells included in the battery package.

In the method, the initial data may include current and voltage feature data for at least one of battery cells included in the battery package.

In the method, the first data may include a first loss function corresponding to the measurement data.

In the method, the second data may include a second loss function corresponding to the initial data.

In the method, the integrated data may include an integrated loss function corresponding to the first data and the second data, and the generating of the digital twin may include generating a digital twin based on a neural network trained with the first data and the second data as input values by using the integrated loss function.

The method may further include adjusting a control signal of the battery package based on a predicted value of the battery package output from the generated digital twin.

According to aspects of the present disclosure, an apparatus for generating a digital twin of a battery package includes a memory in which at least one program is stored and a processor configured to perform an operation by executing the at least one program, in which the processor is further configured to measure a battery package to obtain measurement data and pre-process the obtained measurement data to generate first data, receive initial data for a battery cell included in the battery package and pre-process the received initial data to generate second data, generate integrated data based on the first data and the second data, and generate a digital twin corresponding to the battery package based on the generated integrated data.

In the apparatus, the measurement data may include data about at least one of current, voltage, and temperature received from a battery management system (BMS) of the battery package.

In the apparatus, the initial data may include a pressure for at least one of battery cells included in the battery package.

In the apparatus, the initial data may include an impedance for at least one of battery cells included in the battery package.

In the apparatus, the initial data may include a temperature change curve for at least one of battery cells included in the battery package.

In the apparatus, the initial data may include current and voltage feature data for at least one of battery cells included in the battery package.

In the apparatus, the first data may include a first loss function corresponding to the measurement data.

In the apparatus, the second data may include a second loss function corresponding to the initial data.

In the apparatus, the integrated data may include an integrated loss function corresponding to the first data and the second data, and the processor may be further configured to generate a digital twin based on a neural network trained with the first data and the second data as input values by using the integrated loss function.

According to aspects of the present disclosure, there is provided a computer-readable recording medium storing a program for executing the method.

### BRIEF DESCRIPTION OF THE DRAWINGS

FIG. 1 is a view for schematically describing a method according to the present disclosure;

FIG. 2 is a block diagram of an example of a digital twin generation apparatus according to the present disclosure;

FIG. 3 is a block diagram of an example of a lower module included in a processor described with reference to FIG. 2;

FIG. 4 is a view for describing an example of initial data of a battery cell, input as training data to an artificial intelligence (AI) model according to the present disclosure;

FIGS. 5 and 6 are graphs showing changes in initial charging and discharging characteristics of a battery cell depending on a level of pressure applied to a battery cell;

FIGS. 7 and 8 are graphs showing changes in initial charging and discharging characteristics of a battery cell as an interfacial resistance value extractable from impedance data of the battery cell changes; and

FIG. 9 is a flowchart showing an example of a method according to the present disclosure.

### DETAILED DESCRIPTION

The present disclosure may have various modifications thereto and various embodiments, and thus particular embodiments will be illustrated in the drawings and described in detail in a detailed description. Effects and features of the present disclosure, and methods for achieving them will become clear with reference to the embodiments described later in detail together with the drawings. However, the present disclosure is not limited to the embodiments disclosed herein and may be implemented in various forms.

Hereinafter, embodiments will be described in detail with reference to the accompanying drawings, and in description with reference to the drawings, the same or corresponding components are given the same reference numerals, and redundant description thereto will be omitted.

In the following embodiments, the terms such as first, second, etc., have been used to distinguish one component from other components, rather than limiting.

In the following embodiments, singular forms include plural forms unless apparently indicated otherwise contextually.

In the following embodiments, the terms “include”, “have”, or the like, are intended to mean that there are features, or components, described herein, but do not preclude the possibility of adding one or more other features or components.

When a certain embodiment may be implemented otherwise, a particular process order may be performed differently from the order described. For example, two processes described in succession may be performed substantially simultaneously, or may be performed in an order reverse to the order described.

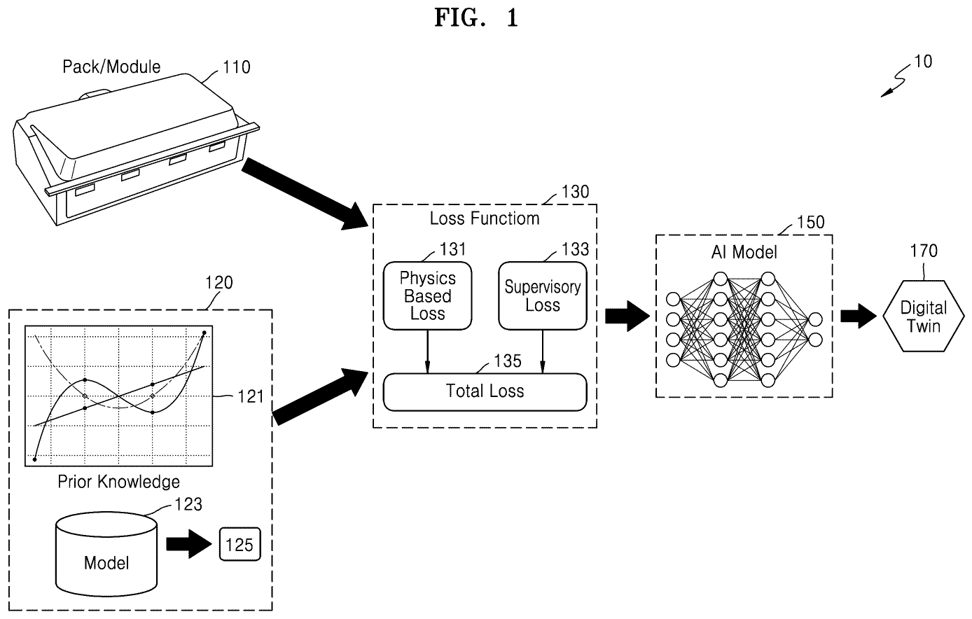

FIG. 1 is a view for schematically describing a method according to the present disclosure.

More specifically, FIG. 1 is a view for individually describing data used in the method according to the present disclosure, and hereinafter, a system shown in FIG. 1 may be abbreviated as a digital twin generation system 10 of a battery package.

A battery package 110 of FIG. 1 refers to a package type battery that is made by combining multiple battery cells into one system. The battery package 110 may include at least two battery modules, and the battery modules included in the battery package 110 may include at least two battery cells as a unit. A battery module may mean a battery group in which at least two battery cells are connected together, or, depending on an embodiment, may mean the entire module in which at least two battery cells are connected together and a sensor capable of sensing basic information such as voltages and currents of the battery cells is additionally added. A battery cell may refer to a unit that includes basic elements of a battery, and when the battery cell is a battery cell for a lithium-ion battery, each battery cell may include a positive electrode, a negative electrode, an electrolyte, and a separator.

The battery package 110 of FIG. 1 may include at least two battery modules as described herein, and may also include a battery management system (BMS) that controls to enable control and cooling for each battery cell or module. In the present disclosure, measurement data measured in a battery control system of the battery package 110 may be used to generate a digital twin for the battery package 110, and the measurement data may be continuously collected over time from the battery package 110 operating as a battery. Data obtained by pre-processing the measurement data may be referred to as first data in the present disclosure.

Non-measurement data 120 of FIG. 1 may refer to the remaining data excluding the measurement data collected in real time in an operating process of the battery package 110. The present disclosure may include a process of additionally considering non-measurement data in addition to the measurement data collected from the battery package 110 in generating a digital twin of the battery package 110 operating in real time, as shown in FIG. 1. The non-measurement data 120 may mean information that is not collected from the battery package 110, but quantifies various physical features of the battery cells, which are the unit constituting the battery package 110. The non-measurement data 120 may be simply a single value or table-type information, or may be information in the form of a mathematical function or feature curve. The non-measurement data 120 of FIG. 1 is feature information guaranteed by a manufacturer that manufactures the battery cell, and may mean information that needs to be considered because the battery cell is not an intangible device like software, but is hardware having an actual volume and having physical properties and durability that change over time. The non-measurement data 120 may vary depending on the manufacturer of the battery cell, the size of the battery cell, the type of the battery cell (lithium ion, lithium iron phosphate, etc.), the manufacturing date of the battery cell, etc.

The non-measurement data 120 may be physical feature information of a battery cell constituting the battery package 110, and may be a type of prior knowledge, but may not be generally considered in a process of simulating the operation of the battery package 110, and the present disclosure may include a process of generating and verifying a digital twin based on the non-measurement data 120.

The non-measurement data 120 of FIG. 1 may include initial feature information 121 of the battery cell and output data of a digital twin model 123 generated merely with measurement data as in the related art.

The initial feature information 121 of the battery cell may refer to initial data obtained in a process of developing the battery cell. The initial feature information 121 of the battery cell may be physical information of the battery cell, and may not be continuously accumulated and collected over time unlike measurement data, but when the initial feature information 121 is information that may be expressed as a function having a relationship, it may be in the form of time-series data.

In FIG. 1, the digital twin model 123 generated using the measurement data may refer to a model designed to simulate a function of the battery package 110 merely with the measurement data of the battery package 110. For example, the digital twin model 123 generated merely with the measurement data may simulate the operation of the battery package 110 and output data predicted as the output data of the battery package 110. In FIG. 1, the data output from the digital twin model 123 generated merely with the measurement data will be referred to as measurement model prediction data 125.

Unlike a completed digital twin 170 generated by the method according to the present disclosure, the digital twin model 123 generated merely with the measurement data of FIG. 1 may not accurately simulate the battery package 110 in a situation where the battery cell included in the battery package 110 does not operate normally, such as when the battery cell included in the battery package 110 deteriorates or is subjected to an impact. The digital twin model 123 generated merely with the measurement data of FIG. 1 may be, but not limited to, a deep learning model based on a neural network.

The non-measurement data 120 may be transmitted to a data integration module 130 of FIG. 1 and processed like the measurement data of the battery package 110. The non-measurement data 120 may be integrated with the measurement data of the battery package 110, and the data obtained by pre-processing the non-measurement data 120 may be abbreviated as second data.

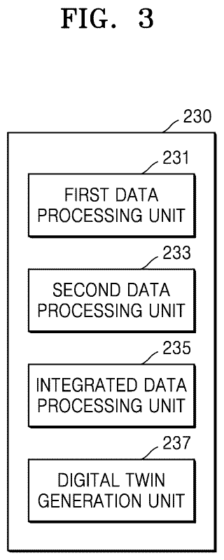

The data integration module 130 of FIG. 1 may receive the measurement data and the non-measurement data 120 of the battery package 110 and perform a data integration process to generate the completed digital twin 170. The data integration module 130 may be implemented as a physical or logical module and may perform the same function as an integrated data processing unit 235 of FIG. 3 described herein. For example, the data integration module 130 may collect and pre-process the measurement data and the non-measurement data 120 of the battery package 110, generate first data and second data, and integrate the first data and the second data. As another example, the data integration module 130 may omit the pre-processing process and perform a process of receiving and integrating first data obtained by pre-processing the measurement data of the battery package 110 and second data obtained by pre-processing the non-measurement data 120.

As a selective embodiment, when the completed digital twin 170 generated according to the present disclosure is a deep learning model based on a neural network, the data integration module 130 may generate a first loss function (1st loss function) based on the measurement data of the battery package 110 and generate a second loss function (2nd loss function) based on the non-measurement data 120. The first loss function may be a supervisory loss function 131 reflecting real-time output data of the battery package 110, and the second loss function may be a physics-based loss function 133 reflecting physical features of the non-measurement data 120. The data integration module 130 may generate an integrated loss function 135 by integrating the supervisory loss function 131 and the physics-based loss function 133. The herein-described embodiment assumes that the completed digital twin 170 is a deep learning model based on a neural network, and may not be applied when the completed digital twin 170 is implemented as a different AI model. The integrated loss function 135 will be described later in FIG. 3.

A model training module 150 of FIG. 1 may train an AI model based on the data output from the data integration module 130. As the data output from the data integration module 130 basically reflects the features of both the measurement data and the non-measurement data 120 of the battery package 110, the completed digital twin 170 that operates most similarly to the actual operation of the battery package 110 may be generated as the AI model is repeatedly trained by the model training module 150.

The model training module 150 may control the neural network based on the integrated loss function 135 generated by the data integration module 130. The neural network controlled by the model training module 150 may be a multi-layer neural network including an input layer, one or more hidden layers, and an output layer. The model training module 150 may control the AI model to be repeatedly trained to minimize a loss of the integrated loss function 135 by a hyper parameter of the neural network by applying the integrated loss function 135 to the loss function layer connected to the output layer. When the loss of the integrated loss function 135 is minimized, the completed digital twin 170 may be generated based on the minimization of the loss. In FIG. 1, it is shown that the model training module 150 trains the neural network-based AI model of a multi-layer perceptron, but as the present disclosure does not specify the type or method of the model trained by the model training module 150, various AI models may be applied depending on an embodiment.

As the completed digital twin 170 of FIG. 1 is a digital twin generated by considering not only real-time measured data from the battery package 110 but also the non-measurement data 120 that is initial data of the battery cells constituting the battery package 110, the completed digital twin 170 may simulate the operation of the battery package 110 more accurately than the digital twin model 123 generated merely with the measurement data.

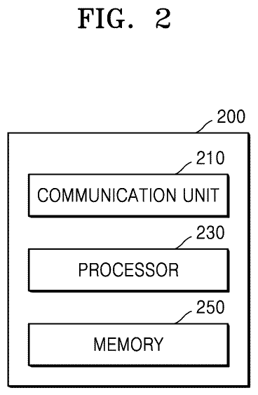

FIG. 2 is a block diagram of an example of a digital twin generation apparatus according to the present disclosure.

Referring to FIG. 2, it may be seen that a digital twin generation apparatus 200 may include a communication unit 210, a processor 230, and a memory 250.

The communication unit 210 may include one or more components that enable the digital twin generation apparatus 200 to perform wired/wireless communication with an external device. For example, the communication unit 210 may include at least one piece of hardware necessary to implement short-range communication such as WiFi or Bluetooth in a network provided by a communication network, or to implement various communications including the Internet when a LAN cable is connected. As an example, the digital twin generation apparatus 200 may receive the measurement data and the non-measurement data 120 of the battery package 110 through the communication unit 210.

The memory 250 may be hardware that stores various data processed in the digital twin generation apparatus 200 and may store programs for processing and control of the processor 230. The memory 250 may include random access memory (RAM) such as dynamic random access memory (DRAM), static random access memory (SRAM), etc., read-only memory (ROM), electrically erasable programmable read-only memory (EEPROM), CD-ROM, Blu-ray or other optical disk storages, hard disk drive (HDD), solid state drive (SSD), or flash memory.

The processor 230 may control overall operations of the digital twin generation apparatus 200. For example, the processor 230 may control the operations of an input unit (not shown), a display (not shown), the communication unit 210, the memory 250, etc., included in the digital twin generation apparatus 200 by executing programs stored in the memory 250.

For example, the processor 230 may measure a battery package to obtain measurement data, pre-process the obtained measurement data to generate first data, receive initial data for battery cells included in the battery package, pre-process the received initial data to generate second data, generate integrated data based on the first data and the second data, and generate a digital twin corresponding to the battery package based on the generated integrated data. A specific process of the processor 230 will be described later with reference to FIGS. 3 to 6.

When the digital twin generation apparatus 200 is implemented as a physical device, the processor 230 may be implemented using at least one of an application specific integrated circuit (ASIC), a digital signal processor (DSP), a digital signal processing device (DSPD), a programmable logic device (PLD), a field programmable gate array (FPGA), a controller, a micro-controller, a microprocessor, and other electric units for performing functions.

When the digital twin generation apparatus 200 is implemented in the form of an application (program) that runs on an integrated data processing device such as a server in the present disclosure, the processor 230 and the memory 250 included in the digital twin generation apparatus 200 may be implemented in the form of a virtual machine that implements hardware such as a DSP, a microcontroller, RAM, ROM, HDD, etc., as software (a command script).

FIG. 3 is a block diagram of an example of a lower module included in a processor described with reference to FIG. 2.

Hereinbelow, a description will be made with reference to FIGS. 1 and 2.

Referring to FIG. 3, it may be seen that the processor 230 includes a first data processing unit 231, a second data processing unit 233, the integrated data processing unit 235, and a digital twin generation unit 237. The first data processing unit 231, the second data processing unit 233, the integrated data processing unit 235, and the digital twin generation unit 237 shown in FIG. 3 may be modules that are logically and conceptually separated to describe a process performed by the processor 230 in a process of implementing a digital twin generation method according to the present disclosure, such that four lower modules are shown in FIG. 3, but the processor 230 may include lower modules that are fewer or more than four depending on an embodiment.

The first data processing unit 231, the second data processing unit 233, the integrated data processing unit 235, and the digital twin generation unit 237 of FIG. 3 are lower modules of the processor 230, and thus, like the processor 230, may be implemented using at least one of an ASIC, a DSP, a DSPD, a PLD, a FPGA, a controller, a micro-controller, a microprocessor, and other electrical units for performing functions.

The first data processing unit 231 may perform data processing to measure the battery package 110 to obtain measurement data and pre-process the obtained measurement data to generate first data. The measurement data may be data about at least one of current, voltage, and temperature of the battery package 110 received from a BMS included in the battery package 110.

The pre-processing process performed by the first data processing unit 231 may include various processes. For example, the pre-processing process performed by the first data processing unit 231 may be a data processing process that processes the measurement data of the battery package 110 into the most suitable loss function when a neural network-based model is trained with the measurement data. The first data may be the first loss function corresponding to the measurement data.

As another example, the pre-processing process performed by the first data processing unit 231 may be a data processing process for performing synchronization with the second data described herein. In FIG. 1, the measurement data measured from the battery package 110 may be real-time time-series data that is continuously collected over time while the battery package 110 is in operation, and the non-measurement data 120 of FIG. 1 may be initial data that reflects the performance/lifetime features of the battery cell regardless of the passage of time from the current point in time when the battery package 110 is measured, such that a process for performing synchronization to integrate different data collection cycles and data collection features may be included in the pre-processing process. The pre-processing process performed by the first data processing unit 231 may be a process that includes all of the embodiments described herein.

The second data processing unit 233 may perform data processing to receive initial data for a battery cell included in the battery package 110 and pre-process the received initial data to generate second data.

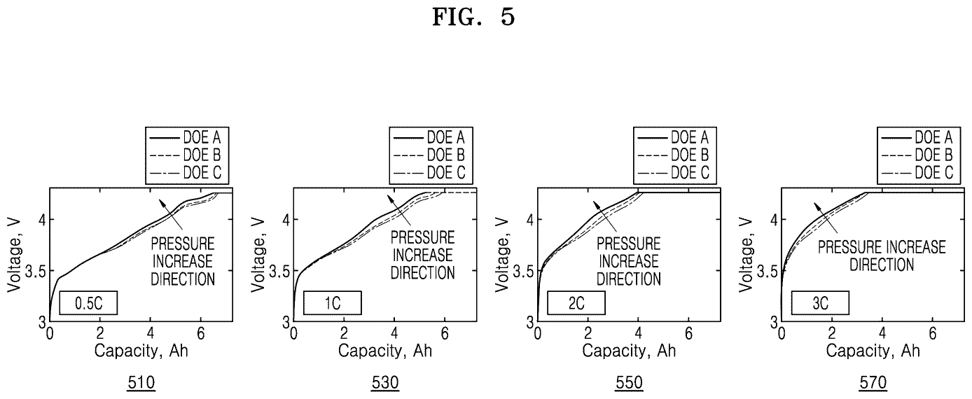

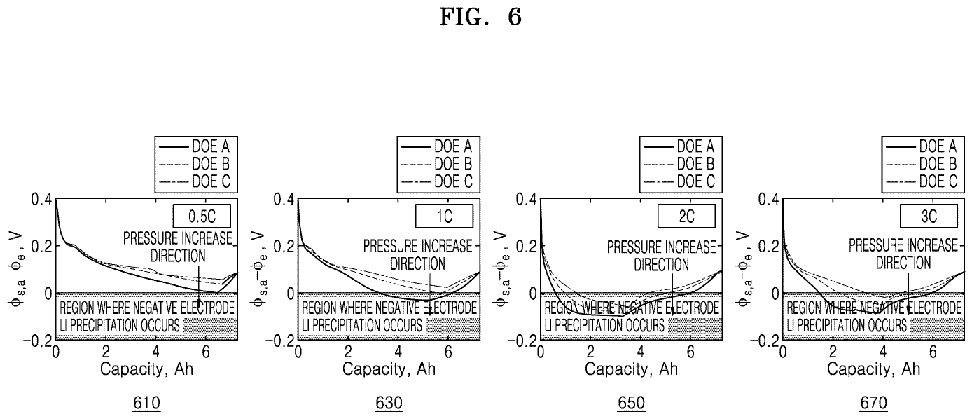

For example, the initial data may be a pressure for at least one of the battery cells included in the battery package 110. In the present disclosure, a case where the initial data for the battery cell is the pressure of the battery cell will be specifically described with reference to FIGS. 5 and 6.

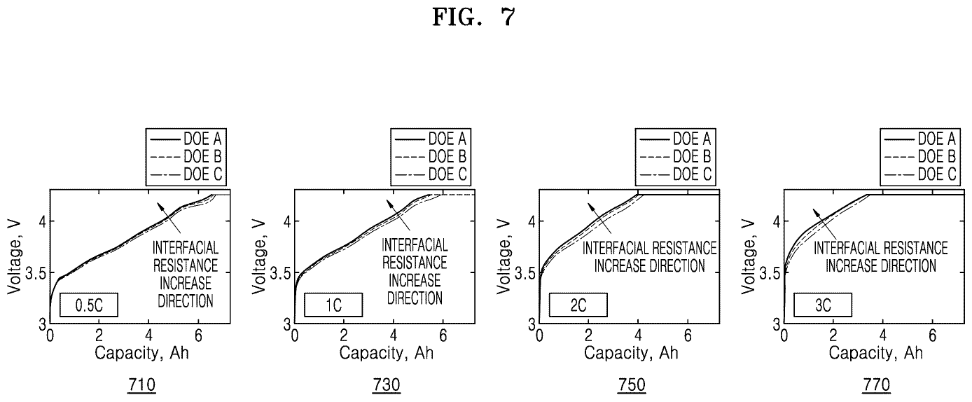

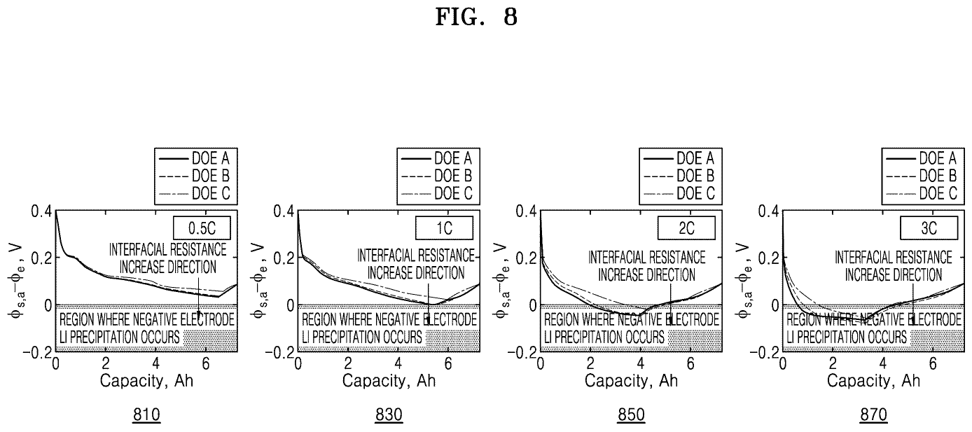

As another example, the initial data may be an impedance for at least one of the battery cells included in the battery package 110. In the present disclosure, a case where the initial data for the battery cell is the impedance of the battery cell will be specifically described with reference to FIGS. 7 and 8.

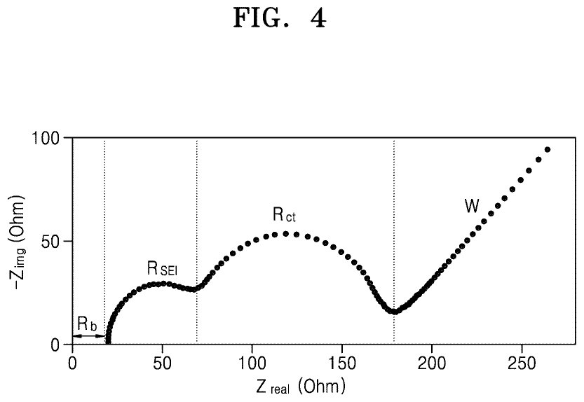

As another example, the initial data may be a temperature change curve for at least one of the battery cells included in the battery package 110. As another example, the initial data may be current and voltage feature data for at least one of the battery cells included in the battery package 110. In the present disclosure, a case where the initial data for the battery cell is the temperature change curve of the battery cell will be later described with reference to FIG. 4.

The pre-processing process performed by the second data processing unit 233 may include various processes. For example, the pre-processing process performed by the second data processing unit 233 may be a data processing process that processes the initial data of the battery package 110 into the most suitable loss function when the neural network-based model is trained with the measurement data. The second data may be a second loss function corresponding to the initial data of the battery cell.

In a process of the first data processing unit 231 and the second data processing unit 233 generating the first loss function and the second loss function, data features or types of the measurement data and the non-measurement data 120 of the battery package 110 may be determined, and according to the determined data features or types, a loss function may be selected from a plurality of predefined loss function groups, and when necessary, a new loss function may be customized to generate a custom loss function.

For example, PyTorch is an open source machine learning library for Python that variously provides a loss function that calculates a mean squared error, a loss function that calculates a mean absolute error, a loss function that calculates a cross entropy loss, a loss function that calculates a negative log likelihood loss, and a loss function that calculates Kullback-Leibler divergence, and the first data processing unit 231 and the second data processing unit 233 may generate their respective loss functions by selecting a loss function suitable for the measurement data and the non-measurement data 120 of the battery package 110 from among the loss functions predefined using PyTorch.

The integrated data processing unit 235 may generate integrated data based on the first data and the second data. The integrated data may be the integrated loss function 135 corresponding to the first data and the second data. Applying the integrated loss function 135 to the AI model may result in inputting the measurement data and the non-measurement data 120 of the battery package 110, which are sources of the first data and the second data, as input values to a digital twin before training is performed.

The digital twin generation unit 237 may generate a digital twin corresponding to the battery package 110 based on the integrated data generated by the integrated data processing unit 235. The digital twin generation unit 237 may generate the digital twin based on the neural network trained using the first data and the second data as input values. That is, the integrated loss function 135 may be transmitted to the digital twin generation unit 237 and used in the process of repeatedly training the neural network.

As selective embodiments, the integrated loss function 135 may be a weighted loss function for the second loss function. For example, the integrated loss function 135 may include the first loss function and the second loss function with a weight value being applied. A weight value λ (lambda) applied to the second loss function may be treated as a hyperparameter and may be appropriately determined in the process of generating a digital twin by the digital twin generation unit 237.

The digital twin generation unit 237 may adjust a control signal of the battery package 110 based on a predicted value of the battery package 110 output from the digital twin. The digital twin generation unit 237 may adjust the control signal of the battery package 110 to verify the predictive performance of the completed digital twin 170 generated based on the feature information of the battery cell, because it is impossible to independently control the battery cell in the battery module or battery package 110.

Through the foregoing process, the digital twin generation apparatus 200 according to the present disclosure may generate a sophisticated digital twin for the battery package 110. The digital twin generated according to the present disclosure is a digital twin generated by combining voltage, current, and temperature values of the battery package 110 measured in real time through the BMS with the initial data of the battery cell obtained in a process of developing the battery cell, such that the performance and lifetime of the battery package 110 may be accurately predicted while accurately simulating the operation of the battery package 110. As it is possible to accurately predict the future operating features of the battery package 110 as described herein, the lifetime of the battery cells included in the battery package 110 and the lifetime of the entire battery package 110 may be improved by appropriately changing the charging/discharging conditions of the battery package 110.

The digital twin generation apparatus 200 according to the present disclosure may include a component that uses initial data of a battery cell, which is a minimum unit constituting the battery package 110, in a process of generating the digital twin of the battery package 110, and, through a verification process that adjusts the control signal for the battery package 110 through the predicted operation of the battery package 110 after the completed digital twin 170 is generated, may derive a correlation between the initial data of the battery cell and a battery module/battery package generated from the battery cell, and provide a user with basic data for developing a control algorithm for finding appropriate usage conditions of the battery package.

FIG. 4 is a view for describing an example of initial data of a battery cell, input as training data to an AI model according to the present disclosure.

As described for the second data processing unit 233 of FIG. 3, the pressure and impedance data measured during the process of developing the battery cells constituting the battery package 110 may be used as input values for training the digital twin model as the initial data of the battery cells. “Battery internal state variables” may include the thickness of a pole plate of the battery cell, the porosity of the battery cell, the tortuosity of the battery cell, an open circuit potential (OCP) of a material of the battery cell, the interfacial resistance of the battery cell, the film resistance of the battery cell, etc. In the present disclosure, in the process of developing the battery cell, a relationship (function) between the features of the battery cell and the pressure may be obtained to use the pressure as an input value for training the digital twin.

$$Measurement Data = f ( v 1 , v 2 , v 3 , … , {v}_{n} ) = f ( Battery Internal State Variable ) \qquad [ Equation 1 ]$$

$$Battery Internal State Variable = g ( {P}_{batt} ) \qquad [ Equation 2 ]$$

Equation 1 and Equation 2 mathematically express a relationship between the internal state variable of the battery and the pressure of the battery cell. In Equation 1, “measurement data” may refer to measurement data of the battery package 110, and mean values for voltage, current, and temperature of the battery package 110. In Equation 1, vᵢ to vₙ may represent “battery internal state variables”, and there may be a total of n battery internal variables (where n is a natural number). As described herein, the battery internal state variables may include the thickness of a pole plate of the battery cell, the porosity of the battery cell, the tortuosity of the battery cell, an OCP of a material of the battery cell, the interfacial resistance of the battery cell, the film resistance of the battery cell, etc. Equation 1 may mean that the measurement data of the battery package 110, such as voltage, current, and temperature of the battery package 110, may be determined by a function f that uses the battery internal state variables as parameters.

Meanwhile, in Equation 2, g may mean a function that has P_{batt} indicating the pressure of the battery cell as its sole parameter. Equation 2 may mean that in the function g, the battery internal state variables changes dependently of each change of the pressure of the battery cell, P_{batt}. When Equation 1 and Equation 2 are interpreted in combination, the battery internal state variables may change as the pressure of the battery cell, P_{batt}, changes, and thus the measurement data of the battery package 110, such as voltage, current, and temperature, may also change.

The second data processing unit 233 may obtain information on battery material features from the impedance of the battery cell, which is one of the initial data of the battery cell. For example, R_{ct}, the interfacial resistance of battery material, may correspond to the battery internal state variable of the digital twin, and FIG. 4 shows a graph indicating the relationship in which R_{ct}, the interfacial resistance of battery material, changes with impedance.

FIGS. 5 and 6 are graphs showing changes in initial charging and discharging characteristics of a battery cell depending on a level of pressure applied to a battery cell.

FIG. 5 shows results of changes in the charging voltage curve of a battery cell depending on a rate of change in pressure applied to the battery cell over a first state 510 to a fourth state 570. Referring to FIG. 5, it may be seen that the charge rate features deteriorate as the pressure level of the battery cell increases, and in FIG. 5, for a pressure magnitude for each design of experiments (DOE), C is considered as greatest and A is considered as least.

FIG. 6 shows results in which the risk of lithium (Li) precipitation degradation increases due to a decrease in a negative potential as a pressure level applied to the battery cell increases from a 5th state 610 to an 8th state 670.

In FIGS. 5 and 6, it may be seen that as the pressure for the battery cell increases, a pore within the pole plate decreases, which increases the movement resistance of lithium ions and thus worsens the charging/discharging rate features of the battery cell. Therefore, by measuring the initial pressure level in the process of developing the battery cell and applying the same to the initial performance model, the accuracy of a beginning of life (BOL) model may be improved, and an accurate BOL model may accurately predict the long-term lifetime of the battery cell.

FIGS. 7 and 8 are graphs showing changes in initial charging and discharging characteristics of a battery cell as an interfacial resistance value extractable from impedance data of the battery cell changes.

FIG. 7 shows results of deteriorating charging rate features of the battery cell as an interfacial resistance Ra of the battery cell increases over a 9th state 710 to an 12th state 770. In FIG. 7, for a pressure magnitude for each DOE, C is considered as greatest and A is considered as least.

FIG. 8 shows results in which the risk of lithium precipitation degradation increases due to a decrease in a negative potential as the interfacial resistance Ra of the battery cell increases from a 13th state 810 to a 16th state 870.

In FIGS. 7 and 8, as described in FIGS. 5 and 6, when the digital twin is generated by measuring initial impedance data in the process of developing the battery to train an initial performance model (a digital twin model not trained) with the measured initial impedance data, the accuracy of the BOL model may be improved and the accurate BOL model may accurately predict the long-term lifetime of the battery cell.

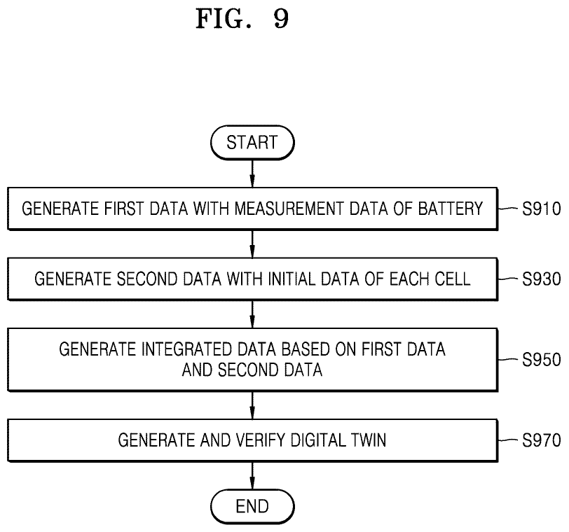

FIG. 9 is a flowchart showing an example of a method according to the present disclosure.

The method according to FIG. 9 may be implemented by the digital twin generation apparatus 200 of FIG. 2, and therefore, will be described with reference to FIGS. 1 to 8, and any description redundant to the foregoing description will be omitted.

In operation S910, the digital twin generation apparatus 200 may perform data processing to measure the battery package 110 to obtain measurement data and pre-process the obtained measurement data to generate first data.

In operation S930, the digital twin generation apparatus 200 may perform data processing to receive initial data for a battery cell included in the battery package 110 and pre-process the received initial data to generate second data.

In operation S950, the digital twin generation apparatus 200 may perform data processing to generate integrated data based on the first data and the second data.

In operation S970, the digital twin generation apparatus 200 may generate and verify the digital twin 170 corresponding to the battery package 110 based on the generated integrated data.

When a digital twin model of a battery package is generated according to a conventionally known method, the physical features of a battery cell may not be reflected, and thus a digital twin model with low accuracy may be inevitably generated in an abnormal situation, but according to the present disclosure, by generating a digital twin by including initial data of the battery cell, the problems of the conventional method may be solved.

Embodiments of the present disclosure described herein may be implemented in the form of a computer program executable on a computer through various components, and the computer program may be recorded on a computer-readable medium. The medium may include a hardware device specially configured to store and execute a program instruction, like a magnetic medium such as a hard disk, a floppy disk, and a magnetic tape, an optical recording medium such as a CD-ROM and a DVD, a magneto-optical medium such as a floptical disk, ROM, RAM, flash memory, etc.

Meanwhile, the computer program may be a program command specially designed and configured for the present disclosure or a program command known to be used by those of ordinary skill in the art of the computer software field. Examples of the computer program may include not only a machine language code created by a complier, but also a high-level language code executable by a computer using an interpreter.

Certain executions described here are embodiments of the present disclosure, not limiting the scope of the present disclosure in any way. For the brevity of the specification, the description of conventional electronic configurations, control systems, software, and other functional aspects of the systems may be omitted. Connections of lines or connection members between components shown in the drawings are illustrative of functional connections and/or physical or circuit connections, and in practice, may be represented as alternative or additional various functional connections, physical connections, or circuit connections. When there is no specific mentioning, such as “essential” or “important”, it may not be a necessary component for the application of the present disclosure.

In the specification (especially, claims) of the present disclosure, the use of the term “the” and similar indicators thereof may correspond to both the singular and the plural. In addition, when the range is described in the present disclosure, the range includes the disclosure to which an individual value falling within the range is applied (unless stated otherwise), and is the same as the description of an individual value constituting the range in the detailed description of the present disclosure. Finally, if there is no apparent description of the order of operations constituting the method according to the present disclosure or a contrary description thereof, the operations may be performed in an appropriate order. However, the present disclosure is not necessarily limited according to the describing order of the operations. The use of all examples or exemplary terms (for example, etc.) in the present disclosure are to simply describe the present disclosure in detail, and unless the range of the present disclosure is not limited by the examples or the exemplary terms unless limited by the claims. In addition, it may be understood by those of ordinary skill in the art that various modifications, combinations, and changes may be made according to design conditions and factors within the scope of the appended claims or equivalents thereof.

According to the present disclosure, a digital twin model that accurately simulates an operation of a battery package may be established.

What is claimed is:

1. A method of generating a digital twin of a battery package, the method comprising:
measuring a battery package to obtain measurement data and pre-processing the obtained measurement data to generate first data;
receiving initial data for a battery cell included in the battery package and pre-processing the received initial data to generate second data;
generating integrated data based on the first data and the second data; and
generating a digital twin corresponding to the battery package based on the generated integrated data.

2. The method of claim 1, wherein the measurement data comprises data about at least one of current, voltage, and temperature received from a battery management system (BMS) of the battery package.

3. The method of claim 1, wherein the initial data comprises a pressure for at least one of battery cells included in the battery package.

4. The method of claim 1, wherein the initial data comprises an impedance for at least one of battery cells included in the battery package.

5. The method of claim 1, wherein the initial data comprises a temperature change curve for at least one of battery cells included in the battery package.

6. The method of claim 1, wherein the initial data comprises current and voltage feature data for at least one of battery cells included in the battery package.

7. The method of claim 1, wherein the first data comprises a first loss function corresponding to the measurement data.

8. The method of claim 1, wherein the second data comprises a second loss function corresponding to the initial data.

9. The method of claim 1, wherein the integrated data comprises an integrated loss function corresponding to the first data and the second data, and
the generating of the digital twin comprises generating a digital twin based on a neural network trained with the first data and the second data as input values by using the integrated loss function.

10. The method of claim 1, further comprising adjusting a control signal of the battery package based on a predicted value of the battery package output from the generated digital twin.

11. A computer-readable recording medium storing a program for executing the method of claim 1.

12. An apparatus for generating a digital twin of a battery package, the apparatus comprising:
a memory in which at least one program is stored; and
a processor configured to perform an operation by executing the at least one program,
wherein the processor is further configured to:
measure a battery package to obtain measurement data and pre-process the obtained measurement data to generate first data;
receive initial data for a battery cell included in the battery package and pre-process the received initial data to generate second data;
generate integrated data based on the first data and the second data; and
generate a digital twin corresponding to the battery package based on the generated integrated data.

13. The apparatus of claim 12, wherein the measurement data comprises data about at least one of current, voltage, and temperature received from a battery management system (BMS) of the battery package.

14. The apparatus of claim 12, wherein the initial data comprises a pressure for at least one of battery cells included in the battery package.

15. The apparatus of claim 12, wherein the initial data comprises an impedance for at least one of battery cells included in the battery package.

16. The apparatus of claim 12, wherein the initial data comprises a temperature change curve for at least one of battery cells included in the battery package.

17. The apparatus of claim 12, wherein the initial data comprises current and voltage feature data for at least one of battery cells included in the battery package.

18. The apparatus of claim 12, wherein the first data comprises a first loss function corresponding to the measurement data.

19. The apparatus of claim 12, wherein the second data comprises a second loss function corresponding to the initial data.

20. The apparatus of claim 12, wherein the integrated data comprises an integrated loss function corresponding to the first data and the second data, and
the processor is further configured to generate a digital twin based on a neural network trained with the first data and the second data as input values by using the integrated loss function.
